(19) United States
(12) Patent Application Publication
(10) Pub. No.: US 2005/0132957 A1
(43) Pub. Date: Jun. 23, 2005

(54) CARRIER BODY AND METHOD

(75) Inventors: Tamer El-Raghy, Voorhees, NJ (US); Edward Laitila, S-737 47 Fagersta (SE); Lena Pettersson, S-737 90 Angelsberg (SE); Gustav Malmqvist, S-734 27 Hallstahammar (SE)

Correspondence Address: WHITE, REDWAY & BROWN LLP, 1217 KING STREET, ALEXANDRIA, VA, 22314, US

(73) Assignees: SECO TOOLS AB, Fagersta (SE); SANDVIK AB, Sandviken (SE)

(21) Appl. No.: 10/905,226

(22) Filed: Dec. 22, 2004

(30) Foreign Application Priority Data
Dec. 22, 2003 (SE) 0303595-3

(51) Int. Cl. C23C 16/00

(52) U.S. Cl. 118/500; 427/248.1

(57) ABSTRACT

The present invention relates to a method and a carrier body for coating cutting tools for chip removal. The carrier body is adapted to be used during coating of cutting tool inserts in a CVD and/or a MTCVD method. The carrier body is at least partially comprised of a material selected from the MAX phase family, i.e. Mn+1AXn (n=1,2,3) wherein M is one or more metals selected from the groups IIIB, IVB, VB, VIB and VIII of the periodic table of elements and/or their mixture, A is one or more metals selected from the groups IIIA, IVA, VA and VIA of the periodic table of elements and/or their mixture, and wherein X is carbon and/or nitrogen.

### BACKGROUND OF THE INVENTION

The present invention relates to a carrier body and a method for coating cutting tools (indexable cutting inserts) for chip removal in accordance with the preambles of the appended independent claims.

CVD (Chemical Vapour Deposition) deposited wear resistant layers, particularly of TiC, Ti(C,N), TiN and Al203 on cemented carbide cutting inserts have been industrially produced for 30 years. Details regarding the deposition condition of CVD and/or MTCVD (Moderate Temperature Chemical Vapour Deposition) layers and the design of CVD and/or MTCVD based layers have been extensively discussed in the literature as well as in patents.

One of the major advantage of the CVD and/or MTCVD technique is the possibility of coating very large numbers of tools in the same batch, up to 30,000 cutting inserts depending on the size of the inserts and the equipment used, which gives a low production cost per insert with coating all-around the cutting insert. In order to obtain a uniform coating thickness distribution it is important that functional surfaces of the cutting insert are relatively equally separated during the coating operation. However, during coating operation not only the tools are coated but also the support on which the cutting inserts rest resulting in that the inserts grow together with the surfaces of the support. When the inserts are removed after the coating cycle is finished contact marks appear at those spots.

These contact marks are not only a cosmetic problem. If they appear on surfaces actually in operation during the metal cutting operation they may lead to a decreased tool life. In addition the support surfaces of an insert must be flat, without protruding marks, in order to avoid erroneous positioning of the cutting insert in the tool holder. An erroneously positioned cutting insert will negatively influence the performance of the cutting tool, i.e. decreased toughness, reduced accuracy and surface finish of the work piece. In order to minimize the negative effect of the contact marks several complicated arrangements have been reported which objective is to move the marks from the functional surfaces to other areas.

Another important aspect of such a system for batch loading of CVD and/or MTCVD coated inserts is that it has to be very flexible for difference in cutting insert geometries. A typical standard CVD and/or MTCVD coating is deposited onto cutting inserts of different size varying from 5 mm in inscribed circle up to 50 mm. The basic shape of the cutting inserts vary, e.g. they can be rectangular, octagonal, square, round, triangular, diamond etc. The cutting inserts can be made with or without a central hole, with different thicknesses varying from 2 mm up to 10 mm. One type of a CVD and/or MTCVD coating cycle will therefore be deposited onto as much as hundreds of different geometries of cutting inserts all needing different arrangements. Therefore, a batch loading system which necessarily needs different arrangement for different cutting insert geometries in order to get a uniform loading density will never work very rational in a production environment focused on low cost and short lead time.

EP 454,686 discloses a loading system, particularly aimed for PACVD, where the cutting inserts are stacked on top of each other on a central pin with or without intermediate spacers. Using this method for CVD and/or MTCVD would get several disadvantage as it is primarily not a universal method, as described above, since different geometries of cutting inserts will need different set-up of the pins. Secondly, a hole is needed on the cutting inserts. Thirdly, when applying thick CVD and/or MTCVD layers the cutting inserts will probably get heavily stuck to the spacer and/or other cutting inserts due to the pressure from the stacked cutting inserts that will enhance the tendency to grow together.

U.S. Pat. No. 5,576,058 discloses a batch loading system based on different arrangement of pegs comprising a foot portion, a shoulder portion, a neck and a head.

A commonly used loading arrangement is to place the cutting inserts into holes or slits in a tray. This method will give contact marks on the cutting edge or on clearance faces of the cutting inserts. This arrangement needs a very careful handling during transportation and loading of the trays in order to avoid that the cutting inserts fall out of their positions. The arrangement is also very difficult to use when automated cutting insert setting is used since the cutting inserts shall be put in very unstable positions.

In yet another method, the cutting inserts are threaded to a rod. The rods may be vertically arranged as in EP 454,686 with the same disadvantages as discussed above, or horizontally. The main drawbacks of the horizontally arrangement is the lack of universality for different cutting inserts geometries, why necessarily a large numbers of different set-ups are needed in order to produce all geometries of cutting inserts. Additionally, this method can only be applied to cutting inserts with a hole.

The most universal arrangements are based on simply placing the cutting inserts on a surface at necessary spacings either on woven metal nets or on some other surface (often made of graphite). The batch is built up by piling the metal nets on top of each other separated by spacers or using graphite carriers onto which the nets are positioned. The great drawback with this method so far has been contact marks between the nets and the cutting inserts that always are formed. These marks give an incorrect positioning of the cutting insert in the tool holder and may give seriously decreased performance of the cutting inserts. Often some post-treatment, such as grinding, may be needed in order to remove protruding marks. Also marks may be found on the cutting edge which also is very negative for cutting insert performance. Another disadvantage with using woven nets is that cutting inserts relatively easily may slide together before deposition thereby resulting in uncoated areas on the cutting insert.

### OBJECTS OF THE INVENTION

It is an object of the present invention to provide a carrier body that avoids formation of contact marks on the cutting inserts during coating.

It is another object of the present invention to provide a carrier body that avoids build-up formations on the cutting inserts during coating.

It is another object of the present invention to provide a method that avoids build-up formations on the cutting inserts during coating.

The objects of the present invention are realized by means of a method and a carrier body having the features defined in the characterizing portions of the appended independent claims.

Definitions

In the following description we will use terms as follows:

Pre-coating(s) define(s) a CVD and/or MTCVD-layer applied onto the net or support material before first time use in the deposition of wear resistant CVD and/or MTCVD layers onto the final product, herein defined as production-coating(s).

### BRIEF DESCRIPTION OF THE DRAWINGS

FIG. 1A shows cross-sections of examples of different geometric shapes of a carrier body according to the present invention that can be used to support cutting inserts.

FIG. 1B shows some of the examples of FIG. 1A in perspective views.

FIG. 2A shows six examples, in side views, of carrier bodies according to the present invention having surface patterns which can be used in a carrier body for single-sided cutting inserts during the coating operation.

FIG. 2B shows another example of a piece of a carrier body according to the present invention in a perspective view for use in coating of single-sided cutting inserts.

### DETAILED DESCRIPTION OF THE INVENTION

By “MAX phase family” as used herein is meant a material comprising Mn+1AXn (n=1,2,3) wherein M is one or more metals selected from the groups IIIB, IVB, VB, VIB and VIII of the periodic table of elements and/or their mixture, A is one or more metals selected from the groups IIIA, IVA, VA and VIA of the periodic table of elements and/or their mixture, and wherein X is carbon and/or nitrogen.

Ti3SiC2 is one material of the MAX phase family and is known for its remarkable properties. It is easily machinable, stiff, thermal shock resistant, damage tolerant, tough, strong at high temperatures, oxidation resistant and corrosion resistant. Yet, it has the density of Ti metal. This material is being considered for several applications such as electric heaters (WO 02/51208), in contact with molten metals (US 2003075251) and for coating of cutting inserts (SE 0202036-0).

According to the present invention it has surprisingly been found that if the surface and/or the carrier body (e.g. pyramids cones, etc.) in contact or in indirect contact with the insert, comprises a material selected from the MAX phase family, it is possible to avoid large contact marks and in particular protruding marks. The properties of the carrier body in contact with the cutting inserts essentially eliminate the problem of prior art.

According to the present invention the material used in direct or indirect contact with the cutting inserts is substantially comprised of a material of the MAX phase family as defined above, preferably more than 85 wt-%.

In one embodiment M one or more metals is/are selected from groups IVB, VB and VIB of the periodic table of elements.

In another embodiment A one or more is/are Si, Al, Ga or Ge.

In yet another embodiment the MAX-phase is of the type n=2 in Mn+1AXn.

In yet another preferred embodiment the MAX-phase is comprised substantially of Ti3SiC2, preferably at least 85 wt-% the rest being one or more of TiC, TiSi2, Ti5Si3 or SiC.

The material is made by methods known in the art such as disclosed in e.g. U.S. Pat. No. 5,942,455.

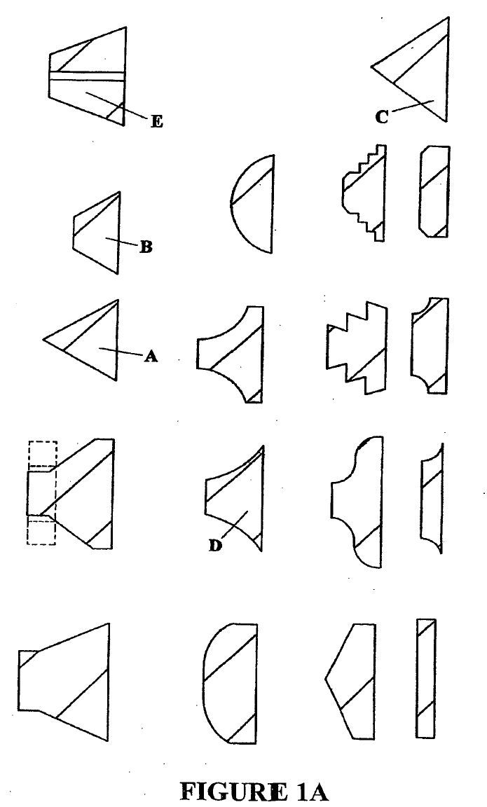

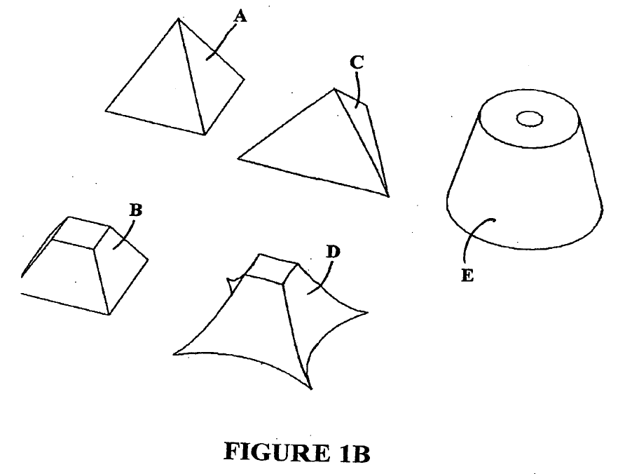

The carrier body can be made in different geometrical shapes in order to suit the actual cutting insert geometry, see FIGS. 1A and 1B where A, B, C, D and E depict shapes shown in both figures. Each carrier body has a base or major surface to contact a support body, not shown. Usually the cutting insert rests upon the carrier body while having a part thereof projecting into the hole of the cutting insert. The dotted lines in one of the examples depict a double-sided cutting insert to be coated. It should be noted the gravity holds the cutting insert to the carrier body in most cases. For cutting inserts with a central hole the shape is preferably made as a pyramid of three or more sides or as a cone. The pyramid corners can also be replaced with a radius between 10 μm and 2 mm. Pyramids with or with or without radii can also be made including concave and/or convex intermediate side sections. In order to guarantee a universal geometry as independent of cutting insert geometry as possible it is preferable that the exposed sides of the pyramid or cone are straight or made as only one single radius, i.e. concave like a trumpet or convex like a bullet.

The pyramids or cones may be truncated to some extent in order to make the handling of them easier. Truncated pyramids or cones can also be used as a support for next supporting body.

Truncated pyramids or cones can also be made with a central hole to improve the gas flow pattern. A desired surface roughness is of the pyramids or cones can also offer advantage.

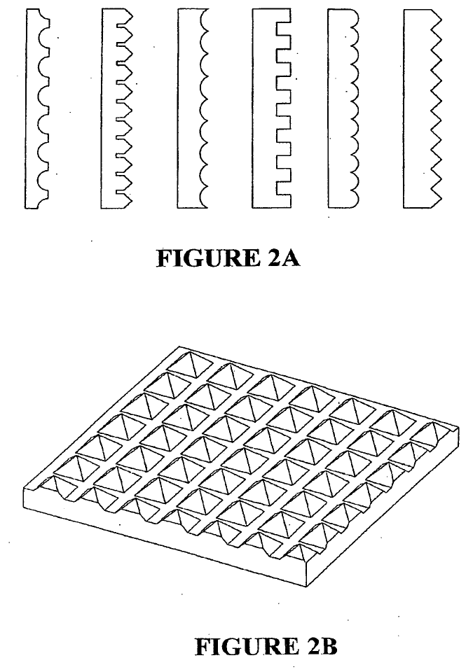

For single-sided cutting inserts, i.e. inserts on which the bottom side will never be used in operation, the cutting inserts can be positioned directly onto a carrier of a material selected from the MAX phase family. This will give thinner layer on the side of the cutting insert against the carrier, but since that side is not functional that is an effect of no importance. The surface can then be made either as flat surface, with or without holes, or as a textured surface. The textured surface can be made as a micro pattern varying in height and in plane dimension regularly or irregularly. FIG. 2A shows six examples of carrier bodies according to the present invention having surface patterns that can be used in a carrier body for single-sided cutting inserts during the coating operation. FIG. 2B shows another example of a piece of a carrier body according to the present invention in a perspective view for use in coating of single-sided cutting inserts. The FIG. 2B can represent either macro or micro geometry.

A preferable regular micro pattern can be pyramids with three or more sides with a base between 50 μm and 5 mm and a height between 20 μm and 5 mm. A blasting, brushing or scratching method to get a micro surface roughness, with a Ra value between 50 μm and 500 μm, can obtain an irregular pattern.

In a preferred embodiment the carrier body is pre-coated with a 5 to 100 μm thick coating of nitride and/or carbide and/or oxide of the metals from groups IVB, VB and VIB of the periodic table, before the first time use for a production coating.

During use as a carrier body for supporting cutting inserts for production coating thicker and thicker coating will be deposited on top of the body. Surprisingly it has been found that this fact does not negatively influence the result. The lifetime of a carrier body according to the present invention as a support material is longer than 50 times production coating without any drop of the favorable properties.

The cutting insert is supposed to be positioned on the carrier body, according to present invention, made of a material selected from the MAX phase family.

The present invention has been described with reference to cutting inserts but it is obvious that it can also be used for the processing of other types of coated components e.g. drills, end-mills, wear parts etc.

At least the area of the carrier body where the cutting tool insert is intended to be located during coating is comprised of a material selected from the MAX phase family. Instead of the entire carrier body being substantially comprised of a material of the MAX phase family it is also conceivable that at least a surface of the carrier body and/or a layer beneath the surface is at least partially comprised of a material selected from the MAX phase family. For example a carrier body of optional material can be coated with at least one surface layer of a material selected from the MAX phase family. The surface layer shall be sufficiently thick to avoid contact marks during coating of tool inserts. The thickness of the surface layer of the carrier body is at least in the magnitude of 25 μm.

### EXAMPLE 1

Four-sided pyramids with straight corners, see FIGS. 1A and 1B variant A, with a base of 10 mm side and a height of 7 mm were produced of the MAX phase material Ti3SiC2 having small amounts of impurities, hereafter called variant A-MAX, and of graphite, called variant A-graphite. The pyramids were positioned on a flat graphite tray with regularly positioned holes of diameter 3 mm. The pyramids were pre-coated with CVD and MTCVD layers of Ti(C,N)+Al203+TiN of a total thickness of 25 μm. Cemented carbide cutting inserts of geometry CNMG120408 for P25 application area were positioned on the every pyramid of the two variants. Totally 100 pyramids per variant were used.

CVD/MTCVD production-coating of Ti(C,N)+A1203+TiN with an approximately 15 μm total coating thickness was deposited on the cutting inserts.

After coating all cutting inserts were examined using a stereo microscope in 10×magnification for marks. The marks were classified with respect to: no visible marks, visible marks smaller than 20 μm height and marks above 20 μm height. The critical size of 20 μm height was chosen since that size is the maximum that can be accepted for good performance of the product.

Cutting inserts measured were coated in first production-coating cycle after pre-coating. Table 1 below summarizes the results.

TABLE 1

| | | | Number of | |
|---|---|---|---|---|
| | | | inserts | |
| | | | with | |
| | Number of | Number of | visible | |
| | inserts | inserts with | marks | |
| | without any | visible marks | above 20 | Degree of |
| | visible mark | below 20 um | um | adhesion |
| Variant A-MAX | 73 | 27 | 0 | Non |
| (invention) | | | | |
| Variant A-graphite | 0 | 62 | 38 | Adhere |
| (prior art) | | | | |

It can clearly be seen that variant A-MAX had less and smaller marks than A-graphite in spite of having the same carrier body geometry. Also, pyramids of A-MAX adhere less. This test demonstrates the advantage of a carrier body of a material selected from the MAX phase family.

### EXAMPLE 2

Single-sided cemented carbide cutting inserts of geometry XOMX0908-ME06 with composition 91 wt. % WC−9 wt. % Co were used. Before deposition the uncoated substrates were cleaned.. A CVD production-coating of Ti(C,N)+Al203+TiN with an approximately 5 μm total coating thickness was deposited on the cutting inserts.

The cutting inserts were positioned directly on a flat tray, similar to the one in FIG. 1A down to the right but larger. The tray consisted of a graphite carrier body comprising essentially Ti3SiC2 having small amounts of impurities, variant A-MAX, and of graphite, variant A-graphite. The thickness of the sectors was 5 mm. The sectors had been pre-coated with a CVD and MTCVD coating of Ti(C,N)+Al203+TiN to a total coating thickness of 20 μm before the test in production coating. Totally 100 cutting inserts per variant were coated.

After production coating all cutting inserts were examined according to example 1.

Cutting inserts measured were coated in first production-coating cycle after pre-coating. Table 2 below summarizes the results.

TABLE 2

| | | | Number of | |
|---|---|---|---|---|
| | | | inserts | |
| | | | with | |
| | Number of | Number of | visible | |
| | inserts | inserts with | marks | |
| | without any | visible marks | above 20 | Degree of |
| | visible mark | below 20 um | um | adhesion |
| Variant A-MAX | 88 | 12 | 0 | Non |
| (invention) | | | | |
| Variant A-graphite | 0 | 77 | 23 | Adhere |
| (prior art) | | | | |

The variant A-MAX of the present invention, clearly shows the best result, the majority of cutting inserts is completely without any marks, and for the one with marks they are smaller than 20 um. Also in this example a clear difference in adherence can be detected.

Thus the present invention relates to a method and a carrier body for coating large volumes of cutting tools and in a rational and productive manner, with hard and wear resistant refractory layers. The method is based on the use of a material selected from the MAX phase family as a durable supporting material used in the coating process. In this way it has been found possible to reduce the drawbacks of the prior art methods i.e. contact marks.

While this invention has been illustrated and described in accordance with a preferred embodiment, it is recognized that variations and changes may be made therein without departing from the invention as set forth in the claims.

1. A carrier body being adapted to carry one or several cutting tool inserts during coating of said cutting tool inserts in a CVD and/or a MTCVD method, wherein at least a surface of the carrier body and/or a layer beneath the surface is at least partially comprised of a material selected from the MAX phase family, i.e. Mn+1AXn (n=1,2,3), wherein M is one or more metals selected from the groups IIIB, IVB, VB, VIB and VIII of the periodic table of elements and/or their mixture, A is one or more metals selected from the groups IIIA, IVA, VA and VIA of the periodic table of elements and/or their mixture, and wherein X is carbon and/or nitrogen.

2. The carrier body according to claim 1, wherein at least the area of the carrier body where the cutting tool insert is intended to be located during coating is comprised of a material selected from the MAX phase family.

3. The carrier body according to claim 1, wherein the entire carrier body is substantially comprised of a material selected from the MAX phase family.

4. The carrier body according to claim 2, wherein the entire carrier body is substantially comprised of a material selected from the MAX phase family.

5. The carrier body according to claim 1, wherein at least one surface layer of the carrier body is substantially comprised of a material selected from the MAX phase family.

6. The carrier body according to claim 5, wherein the surface layer is sufficiently thick to avoid contact marks during coating of tool inserts, the thickness of said surface layer of the carrier body preferably being at least in the magnitude of 25 μm.

7. The carrier body according to claim 2, wherein at least one surface layer of the carrier body is substantially comprised of a material selected from the MAX phase family.

8. The carrier body according to claim 7, wherein the surface layer is sufficiently thick to avoid contact marks during coating of tool inserts, the thickness of said surface layer of the carrier body preferably being at least in the magnitude of 25 μm.

9. The carrier body according to claim 1, wherein the carrier body is a pyramid with three or more sides or a cone.

10. The carrier body according to claim 2, wherein the carrier body is a pyramid with three or more sides or a cone.

11. The carrier body according to claim 3, wherein the carrier body is a pyramid with three or more sides or a cone.

12. The carrier body according to claim 4, wherein the carrier body is a pyramid with three or more sides or a cone.

13. The carrier body according to claim 5, wherein the carrier body is a pyramid with three or more sides or a cone.

14. The carrier body according to claim 6, wherein the carrier body is a pyramid with three or more sides or a cone.

15. The carrier body according to claim 9, wherein the exposed sides of the pyramid or the cone are convex or concave.

16. The carrier body according to claim 1, wherein the material from the MAX phase family is Ti3SiC2.

17. The carrier body according to claim 2, wherein the material from the MAX phase family is Ti3SiC2.

18. A method for coating cutting tool inserts comprising a substrate and a coating deposited using a CVD and/or a MTCVD method, wherein the inserts are positioned on a carrier body as defined in claim 1 during coating.

19. The method according to claim 18, comprising providing the carrier body essentially of Ti3SiC2 as a pyramid with three or more sides or a cone.

20. The method according to claim 18, comprising providing a carrier body essentially of Ti3SiC2 having a flat surface with or without a surface pattern.
